(19) United States
(12) Patent Application Publication
(10) Pub. No.: US 2024/0296673 A1
(43) Pub. Date: Sep. 5, 2024

(54) SYSTEMS AND METHODS FOR VIBRATION ANALYSIS AND MONITORING

(71) Applicant: The Travelers Indemnity Company, Hartford, CT (US)

(72) Inventors: Michael W. Koppang, Holden, MA (US); John P. Machnicki, Somers, CT (US); Robert J. Kreuzer, Terryville, CT (US); Jeffrey J. Lamo, Wethersfield, CT (US); Catherine A. Leek, Mansfield Center, CT (US)

(21) Appl. No.: 18/661,619

(22) Filed: May 11, 2024

Related U.S. Application Data
(63) Continuation of application No. 15/909,915, filed on Mar. 1, 2018, now abandoned.
(60) Provisional application No. 62/467,067, filed on Mar. 3, 2017.

(51) Int. Cl. G06V 20/10; G01V 1/30; G06F 30/00; G06V 10/94; G06V 20/20

(52) U.S. Cl. CPC G06V 20/176; G01V 1/303; G06F 30/00; G06V 10/94; G06V 20/20

(57) ABSTRACT

Systems, methods, and articles of manufacture provide for vibration analysis and monitoring, such as utilizing geo-referenced data to compute a plurality of sensor locations, facilitate sensor placement, identify a plurality of entities that may experience a planned vibration event, document historic or baseline damage, monitor and/or manage vibrations as they occur on site, and/or process vibration activity-related insurance claims.

### CROSS-REFERENCE TO RELATED APPLICATIONS

This disclosure claims benefit and priority under 35 U.S.C. § 120 to, and is a Continuation of, U.S. patent application Ser. No. 15/909,915 filed on Mar. 1, 2018 and titled “SYSTEMS AND METHODS FOR VIBRATION ANALYSIS AND MONITORING”, which itself claims benefit and priority to U.S. Provisional Patent Application No. 62/467,067 titled “SYSTEMS AND METHODS FOR VIBRATION ANALYSIS AND MONITORING” and filed on Mar. 3, 2017, each of which is hereby incorporated by reference herein in its entirety.

### BACKGROUND

Construction activities are often associated with various damage or losses, such as due to large vehicle usage, excavation, blasting, hammering, pile driving, and other related activities. While potential damage can often be mitigated by analyzing planned activities prior to occurrence and implementing best practices, damage may often still occur or be perceived to occur. Due to the sensitivity of human perception to vibratory activities, for example, it is often believed that damage has occurred (e.g., in a nearby building) regardless of whether the activity could actually have caused the alleged damage. Such perceived damage may result in operational losses (e.g., insurance claims, delays, etc.) even in cases where the activity did not cause the alleged damage.

### BRIEF DESCRIPTION OF THE DRAWINGS

An understanding of embodiments described herein and many of the attendant advantages thereof may be readily obtained by reference to the following detailed description when considered with the accompanying drawings, wherein:

FIG. 1 is a block diagram of a system according to some embodiments;

FIG. 2 is a flow diagram of a method according to some embodiments;

FIG. 3 is a perspective diagram of a system according to some embodiments;

FIG. 4 is a plan view of a system according to some embodiments;

FIG. 5 is a perspective diagram of a system according to some embodiments;

FIG. 6 is a perspective diagram of a system according to some embodiments;

FIG. 7 is a block diagram of an apparatus according to some embodiments; and

FIG. 8A, FIG. 8B, FIG. 8C, FIG. 8D, and FIG. 8E are perspective diagrams of exemplary data storage devices according to some embodiments.

### DETAILED DESCRIPTION

### I. Introduction

Construction losses due to vibratory activity damage, as well as alleged damage associated with perceived vibratory activity, are a significant detriment to businesses in a variety of industries. Construction activities are often covered by insurance policies, for example, and the insuring company may often pay for claimed losses that are not likely to have been caused by activities of the insured. Due to the complex nature of construction activities, however, it is often difficult to ascertain the cause of damage or to reasonably disprove a linkage of the activity with an alleged damage event. In some cases, best practice mitigation techniques may be employed to assist in prevention of vibratory impact damage, yet in the event of a claimed loss, mere implementation of preventative measures amounts to only circumstantial evidence of lack of causation.

In accordance with embodiments herein, these and other deficiencies of previous efforts are remedied, such as by providing systems, apparatus, methods, and articles of manufacture for vibration analysis and monitoring. In some embodiments for example, input descriptive of a proposed vibratory activity may be received, compared to stored data of various types, and processed to identify various pre-activity actions intended to more specifically mitigate the effects of the proposed activity and/or to better document the totality of the circumstances involved with the activity. Vibration sensors may be placed in the field in accordance with computed desired sensor locations, for example, and/or specific component actions of a site survey may be suggested and/or conducted. According to some embodiments, vibration readings taken before, during, and/or after the proposed activity may be recorded to develop a mathematical picture or model of vibration activity at a proposed construction (or other) site.

### II. Vibration Analysis and Monitoring

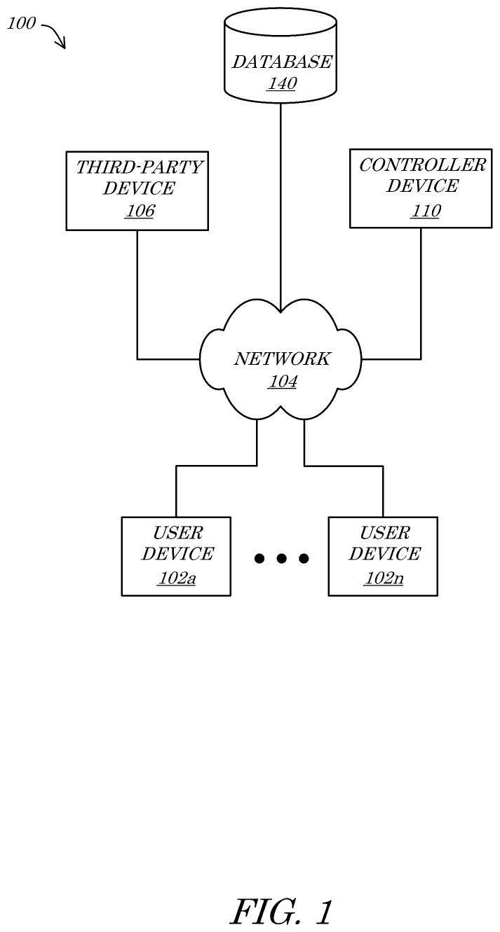

Referring first to FIG. 1, a block diagram of a system 100 according to some embodiments is shown. In some embodiments, the system 100 may comprise a plurality of user devices 102a-n, a network 104, a third-party device 106, a controller device 110, and/or a database 140. As depicted in FIG. 1, any or all of the devices 102a-n, 106, 110, 140 (or any combinations thereof) may be in communication via the network 104. In some embodiments, the system 100 may be utilized to receive vibration activity data, such as site plan data, location data, contact data, permit data, insurance claims data, etc. The controller device 110 may, for example, interface with one or more of the user devices 102a-n and/or the third-party device 106 to receive vibration activity data and process such data in accordance with one or more data processing algorithms or models. In the non-limiting exemplary case of risk-and/or insurance-related analysis, for example, vibration activity data may be analyzed in accordance with a data processing model that (i) identifies appropriate preventative measures and/or specific locations thereof, (ii) identifies one or more sensor types and/or locations, (iii) identifies one or more entities and/or objects of potential concern for vibratory activity damage, and/or (iv) analyzes actual vibration readings (e.g., from the sensor(s)) to determine a likelihood of the activity having caused an alleged damage or loss.

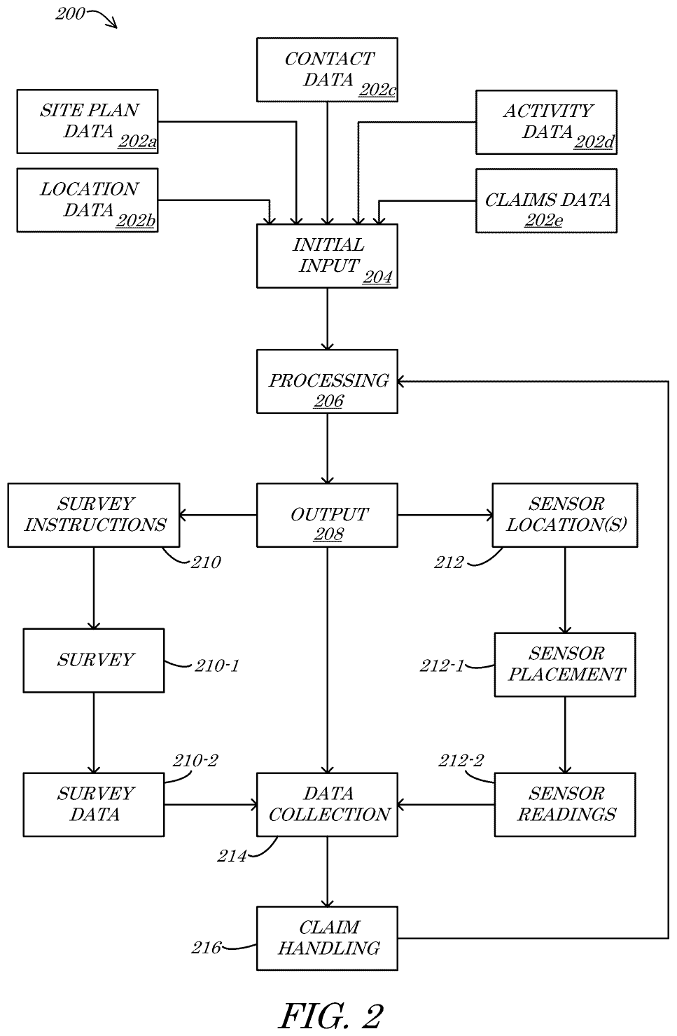

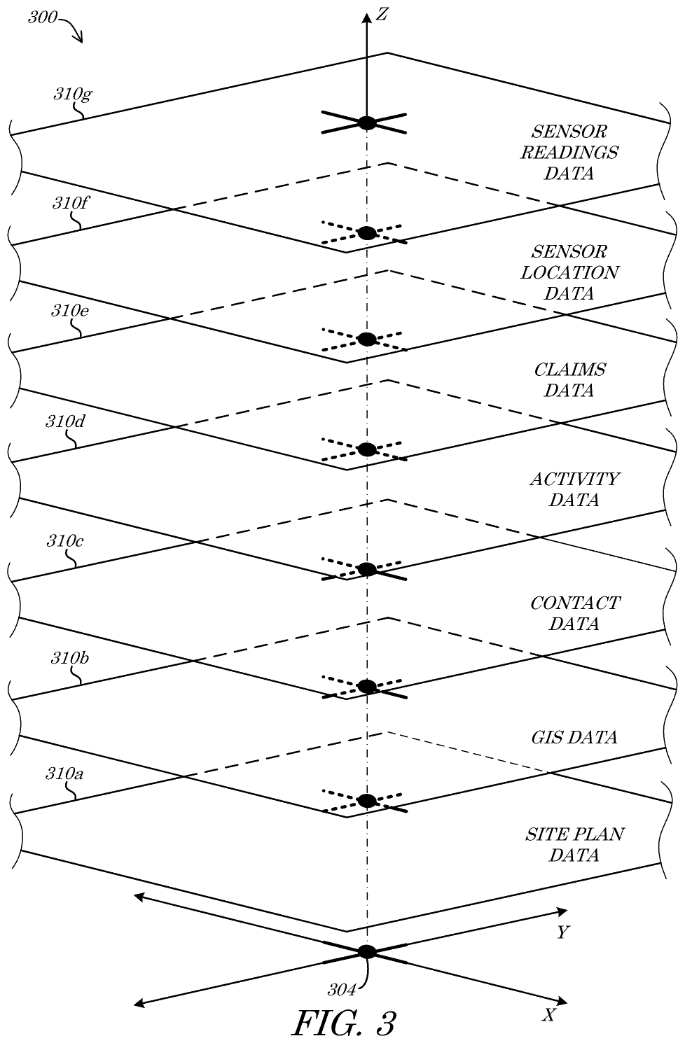

Fewer or more components 102a-n, 104, 106, 110, 140 and/or various configurations of the depicted components 102a-n, 104, 106, 110, 140 may be included in the system 100 without deviating from the scope of embodiments described herein. In some embodiments, the components 102a-n, 104, 106, 110, 140 may be similar in configuration and/or functionality to similarly named and/or numbered components as described herein. In some embodiments, the system 100 (and/or portions thereof) may comprise a risk assessment, site plan design, and/or insurance claims analysis program, system, and/or platform programmed and/or otherwise configured to execute, conduct, and/or facilitate the method 200 of FIG. 2 herein, and/or portions thereof.

The user devices 102a-n, in some embodiments, may comprise any types or configurations of computing, mobile electronic, network, user, and/or communication devices that are or become known or practicable. The user devices 102a-n may, for example, comprise one or more Personal Computer (PC) devices, computer workstations (e.g., an underwriter workstation), tablet computers, such as an iPad® manufactured by Apple®, Inc. of Cupertino, CA, and/or cellular and/or wireless telephones, such as an iPhone® (also manufactured by Apple®, Inc.) or an Optimus™ S smart phone manufactured by LG® Electronics, Inc. of San Diego, CA, and running the Android® operating system from Google®, Inc. of Mountain View, CA. In some embodiments, the user devices 102a-n may comprise devices owned and/or operated by one or more users, such as site plan designers, engineers, claim handlers, field agents, underwriters, account managers, agents/brokers, customer service representatives, data acquisition partners and/or consultants or service providers, and/or underwriting product customers (or potential customers, e.g., consumers). According to some embodiments, the user devices 102a-n may communicate with the controller device 110 via the network 104, such as to conduct analysis of proposed vibration activities and/or conduct processes utilizing vibration event analysis apparatus, systems, articles of manufacture, and/or methods as described herein.

In some embodiments, the user devices 102a-n may interface with the controller device 110 to effectuate communications (direct or indirect) with one or more other user devices 102a-n (such communication not explicitly shown in FIG. 1), such as may be operated by other users. In some embodiments, the user devices 102a-n may interface with the controller device 110 to effectuate communications (direct or indirect) with the third-party device 106 (such communication also not explicitly shown in FIG. 1). In some embodiments, the user devices 102a-n and/or the third-party device 106 may comprise one or more sensors configured and/or coupled to sense, measure, calculate, and/or otherwise process or determine vibration activity data, such as vibration measurements, soil type analysis, moisture readings, depth and/or height readings, weight readings, and/or location readings. In some embodiments, such sensor data may be provided to the controller device 110, such as to analyze proposed vibration activities, analyze ongoing (e.g., current) vibration activities, analyze stored (e.g., previous or historic) vibration activates, conduct claim handling, pricing, risk assessment, line and/or limit setting, quoting, and/or selling or re-selling of an underwriting product.

The network 104 may, according to some embodiments, comprise a Local Area Network (LAN; wireless and/or wired), cellular telephone, Bluetooth®, Near Field Communication (NFC), and/or Radio Frequency (RF) network with communication links between the controller device 110, the user devices 102a-n, the third-party device 106, and/or the database 140. In some embodiments, the network 104 may comprise direct communications links between any or all of the components 102a-n, 106, 110, 140 of the system 100. The user devices 102a-n may, for example, be directly interfaced or connected to one or more of the controller device 110 and/or the third-party device 106 via one or more wires, cables, wireless links, and/or other network components, such network components (e.g., communication links) comprising portions of the network 104. In some embodiments, the network 104 may comprise one or many other links or network components other than those depicted in FIG. 1. The user devices 102a-n may, for example, be connected to the controller device 110 via various cell towers, routers, repeaters, ports, switches, and/or other network components that comprise the Internet and/or a cellular telephone (and/or Public Switched Telephone Network (PSTN)) network, and which comprise portions of the network 104.

While the network 104 is depicted in FIG. 1 as a single object, the network 104 may comprise any number, type, and/or configuration of networks that is or becomes known or practicable. According to some embodiments, the network 104 may comprise a conglomeration of different sub-networks and/or network components interconnected, directly or indirectly, by the components 102a-n, 106, 110, 140 of the system 100. The network 104 may comprise one or more cellular telephone networks with communication links between the user devices 102a-n and the controller device 110, for example, and/or may comprise the Internet, with communication links between the controller device 110 and the third-party device 106 and/or the database 140, for example.

The third-party device 106, in some embodiments, may comprise any type or configuration of a computerized processing device such as a PC, laptop computer, computer server, database system, and/or other electronic device, devices, or any combination thereof. In some embodiments, the third-party device 106 may be owned and/or operated by a third-party (i.e., an entity different than any entity owning and/or operating either the user devices 102a-n or the controller device 110). The third-party device 106 may, for example, be owned and/or operated by data and/or data service provider such as Dun & Bradstreet® Credibility Corporation (and/or a subsidiary thereof, such as Hoovers™), Deloitte® Development, LLC, Experian™ Information Solutions, Inc., and/or Edmunds.com®, Inc. In some embodiments, the third-party device 106 may supply and/or provide data, such as other construction activity data (e.g., based on municipal and/or state permit filings), Global Information System (GIS) data, topographical data, utility location data, and/or entity contact data (e.g., addresses, phone numbers, e-mail addresses, social media contact information, etc.), to the controller device 110 and/or the user devices 102a-n. In some embodiments, the third-party device 106 may comprise a plurality of devices and/or may be associated with a plurality of third-party entities.

In some embodiments, the controller device 110 may comprise an electronic and/or computerized controller device, such as a computer server communicatively coupled to interface with the user devices 102a-n and/or the third-party device 106 (directly and/or indirectly). The controller device 110 may, for example, comprise one or more PowerEdge™ M910 blade servers manufactured by Dell®, Inc. of Round Rock, TX, which may include one or more Eight-Core Intel® Xeon® 7500 Series electronic processing devices. In some embodiments, the controller device 110 may comprise a plurality of processing devices specially programmed to execute and/or conduct processes that are not practicable without the aid of the controller device 110. The controller device 110 may, for example, conduct vibration analysis calculations in real time or near-real time, such calculations not being capable of being timely conducted without the benefit of the specially-programmed controller 110. According to some embodiments, the controller device 110 may be located remote from one or more of the user devices 102a-n and/or the third-party device 106. The controller device 110 may also or alternatively comprise a plurality of electronic processing devices located at one or more various sites and/or locations.

According to some embodiments, the controller device 110 may store and/or execute specially programmed instructions to operate in accordance with embodiments described herein. The controller device 110 may, for example, execute one or more programs that facilitate the provision of analysis calculations as utilized in various industry data processing applications, such as, but not limited to, vibration engineering data analysis, GIS data analysis, insurance and/or risk analysis, and/or handling, processing, pricing, underwriting, and/or issuance of one or more insurance and/or underwriting products and/or claims with respect thereto. According to some embodiments, the controller device 110 may comprise a computerized processing device such as a PC, laptop computer, computer server, and/or other electronic device to manage and/or facilitate transactions and/or communications regarding the user devices 102a-n. An insurance company employee, agent, claim handler, underwriter, and/or other user (e.g., customer, consumer, client, or company) may, for example, utilize the controller device 110 to (i) price and/or underwrite one or more products, such as insurance, indemnity, and/or surety products (e.g., based on vibration analysis calculations) and/or (ii) provide an interface via which a data processing and/or claims analysis entity may manage and/or facilitate vibration analysis calculation data processing, such as for the handling of one or more vibration activity-related insurance claims, in accordance with embodiments described herein.

In some embodiments, the controller device 110 and/or the third-party device 106 (and/or the user devices 102a-n) may be in communication with the database 140. The database 140 may store, for example, site plan data, location data, contact data, activity data, claims data, survey data, and/or sensor data (e.g., obtained from the user devices 102a-n and/or the third-party device 106), and/or instructions that cause various devices (e.g., the controller device 110 and/or the user devices 102a-n) to operate in accordance with embodiments described herein. In some embodiments, the database 140 may comprise any type, configuration, and/or quantity of data storage devices that are or become known or practicable. The database 140 may, for example, comprise an array of optical and/or solid-state hard drives configured to store vibration activity and/or location data provided by (and/or requested by) the user devices 102a-n, survey data, and/or sensor location data. While the database 140 is depicted as a stand-alone component of the system 100 in FIG. 1, the database 140 may comprise multiple components. In some embodiments, a multi-component database 140 may be distributed across various devices and/or may comprise remotely dispersed components. Any or all of the user devices 102a-n or third-party device 106 may comprise the database 140 or a portion thereof, for example, and/or the controller device 110 may comprise the database or a portion thereof.

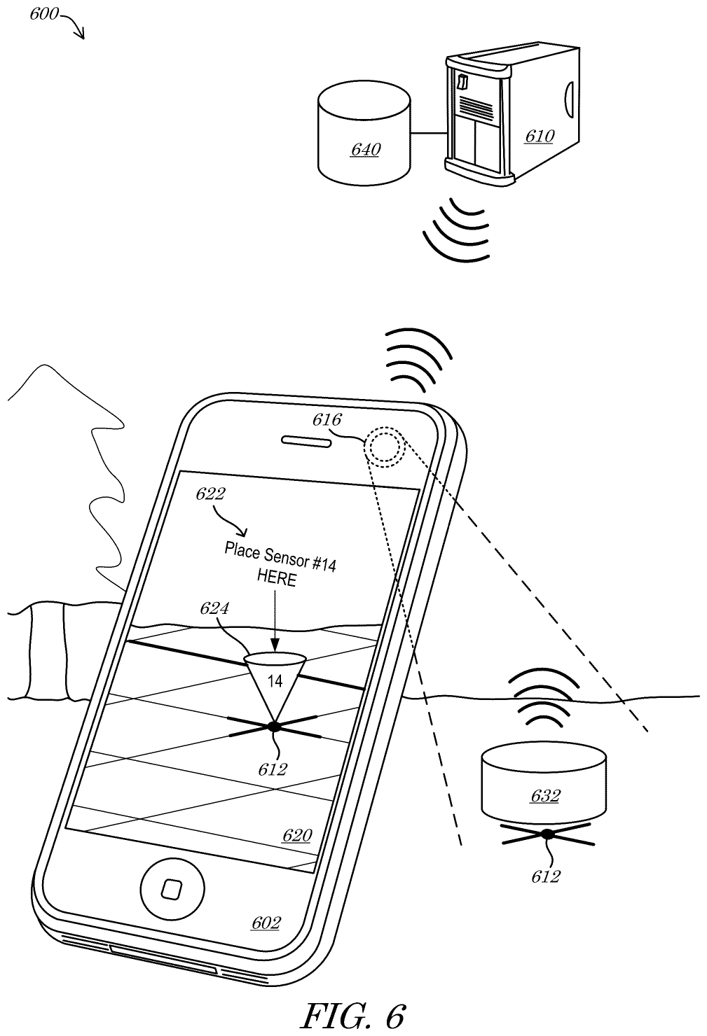

Turning now to FIG. 2, a flow diagram of a method 200 according to some embodiments is shown. In some embodiments, the method 200 may be performed and/or implemented by and/or otherwise associated with one or more specialized and/or specially-programmed computers (e.g., the user devices 102a-n, the third-party device 106, and/or the controller device 110 of FIG. 1 herein), specialized computers, computer terminals, computer servers, computer systems and/or networks, and/or any combinations thereof (e.g., by one or more multi-threaded and/or multi-core processing units of an insurance company data processing system). In some embodiments, the method 200 may be embodied in, facilitated by, and/or otherwise associated with various input mechanisms and/or interfaces (e.g., the interface 620 of FIG. 6 herein).

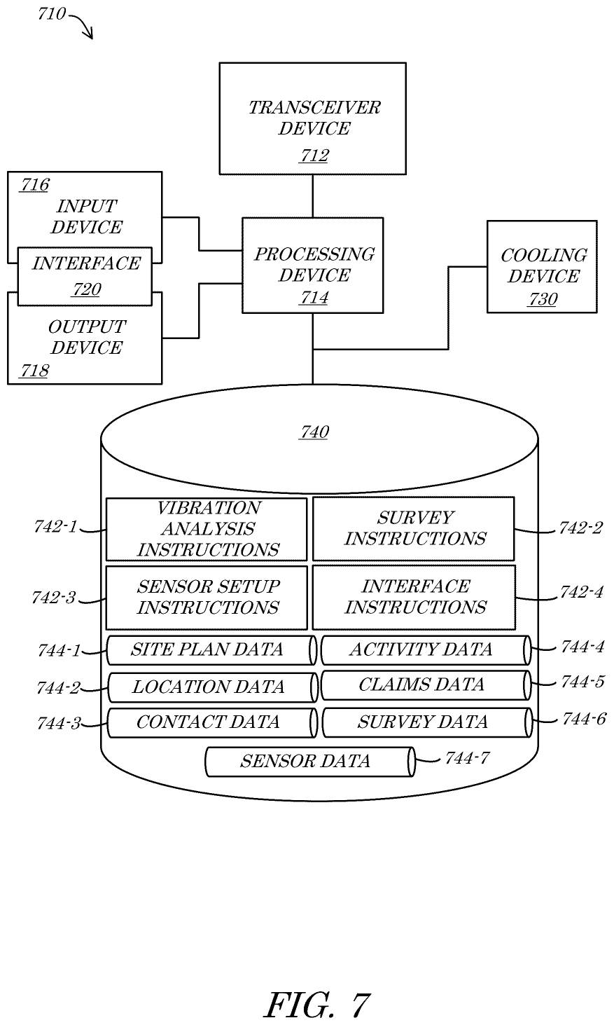

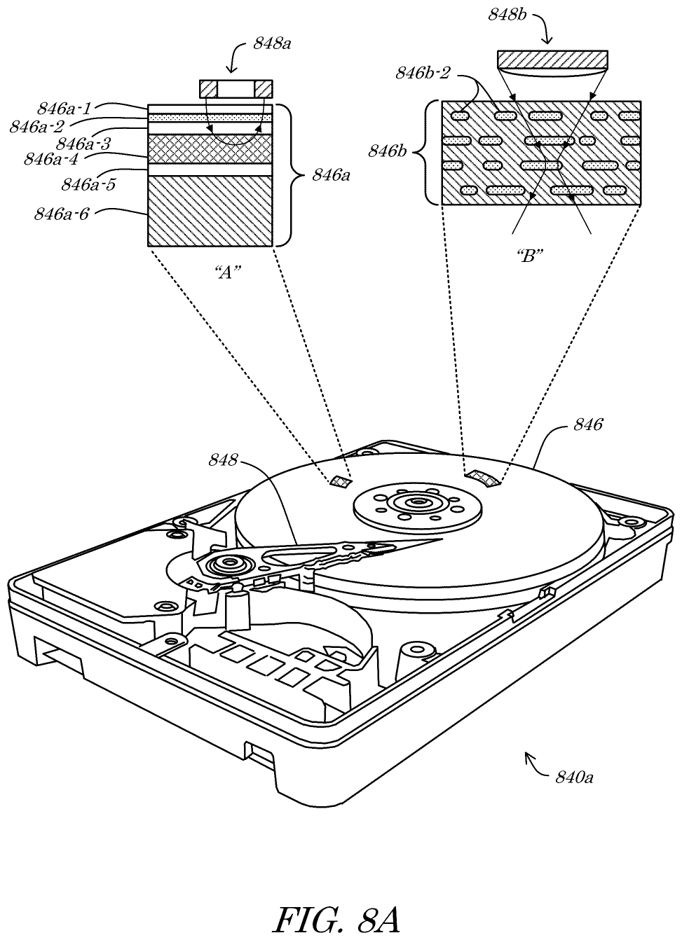

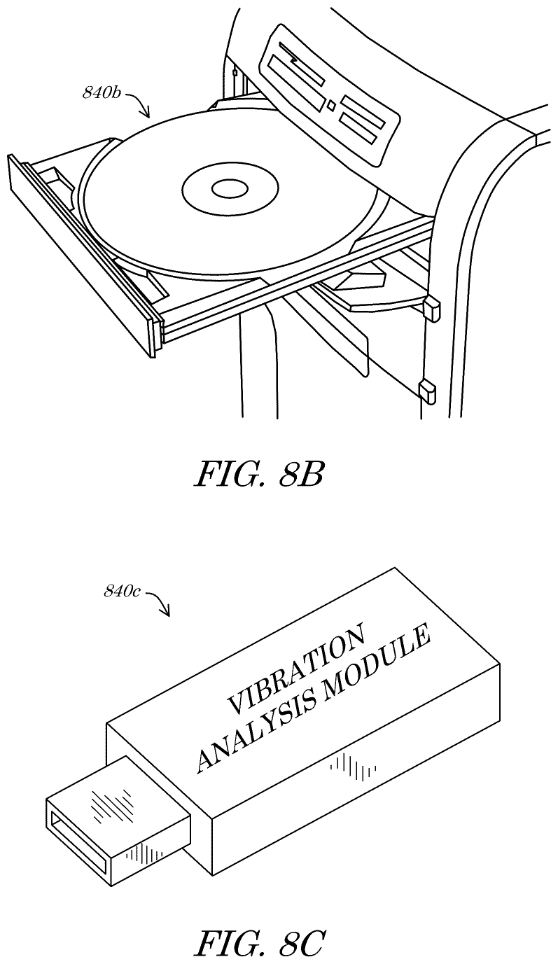

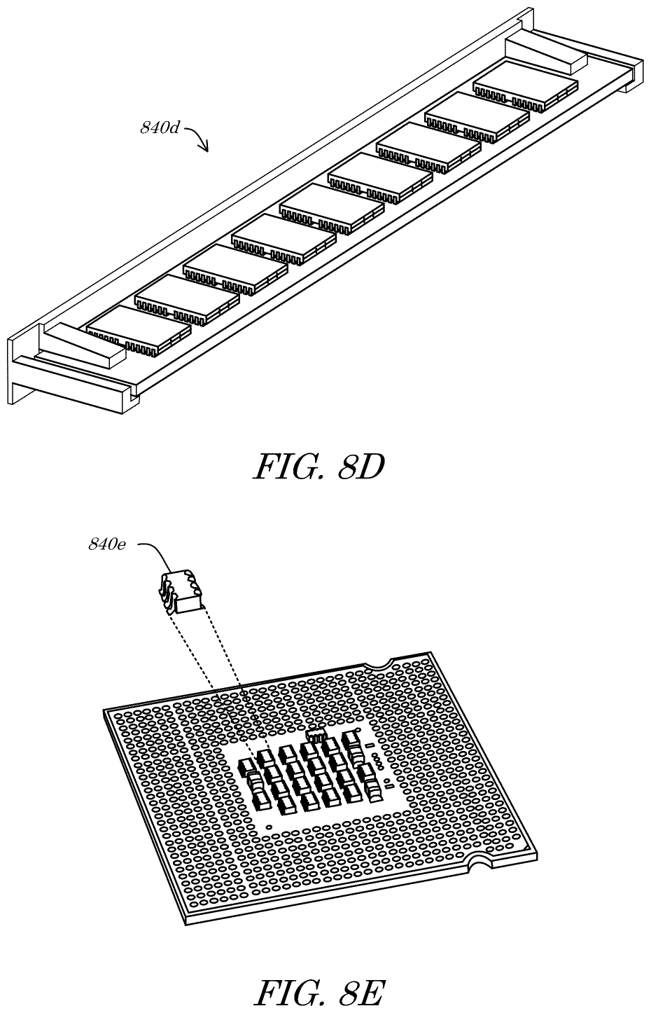

The process diagrams and flow diagrams described herein do not necessarily imply a fixed order to any depicted actions, steps, and/or procedures, and embodiments may generally be performed in any order that is practicable unless otherwise and specifically noted. While the order of actions, steps, and/or procedures described herein is generally not fixed, in some embodiments, actions, steps, and/or procedures may be specifically performed in the order listed, depicted, and/or described and/or may be performed in response to any previously listed, depicted, and/or described action, step, and/or procedure. Any of the processes and methods described herein may be performed and/or facilitated by hardware, software (including microcode), firmware, or any combination thereof. For example, a storage medium (e.g., a hard disk, Random Access Memory (RAM) device, cache memory device, Universal Serial Bus (USB) mass storage device, and/or Digital Video Disk (DVD); e.g., the data storage devices 140, 640, 740, 840a-e of FIG. 1, FIG. 6, FIG. 7, FIG. 8A, FIG. 8B, FIG. 8C, FIG. 8D, and/or FIG. 8E herein) may store thereon instructions that when executed by a machine (such as a computerized processor) result in performance according to any one or more of the embodiments described herein.

According to some embodiments, the method 200 may comprise receiving (and/or otherwise determining; e.g., via an electronic communication and/or network pathway) data (e.g., site plan data 202a, location data 202b, contact data 202c, activity data 202d, and/or claims data 202e) as initial input, at 204. A transceiver and/or server device disposed remotely from a user device (e.g., a wireless and/or portable electronic device operated by a user) may, for example, receive data descriptive of a site plan or other data descriptive of a proposed vibration-related activity, such as the site plan data 202a. The site plan data 202a may, in some embodiments, comprise one or more electronic data files such as a Computer Aided Design (CAD) file and/or data saved by and/or in accordance with a CAD program such as AutoCAD® Civil 3D® 2017 available from Autodesk, Inc. of San Rafael, CA. According to some embodiments, the site plan data 202a may identify and/or define one or more points, locations, and/or types of proposed or planned vibration-related activities (e.g., an indication that a pile driver will be utilized to drive a pile at a particular location). In some embodiments, the location data 202b may comprise data received and/or provided with the site plan data 202a and/or may comprise additional location data, such as GIS data, relevant to the site location of the site plan data 202a. In some embodiments, the contact data 202c may comprises communication address and/or account data, such as mailing addresses, telephone numbers, e-mail addresses, and/or social media account and/or contact information. In some embodiments, the contact data 202c may be geo-tagged and/or geo-referenced. The contact data 202c may, for example, be associated or link certain contact records with certain (e.g., one or more) geographic locations (e.g., as identified by GPS coordinates, latitude and longitude, etc.). According to some embodiments, the activity data 202d may comprise data descriptive of other or third-party activities relevant to the site location of the site plan data 202a. While the site plan data 202a may be submitted and/or provided by a first entity (e.g., an insured) proposing a first construction activity at the identified site, for example, the activity data 202d may identify or define one or more different activities (e.g., planned, current, or past) by, e.g., a different or second entity. The activity data 202d may be sourced, for example, from permit applications for locations proximate to the site location for the proposed activity of the first entity (e.g., within a predetermined range of the site, such as within one hundred (100) yards). In some embodiments, the claims data 202e may comprise data descriptive of one or more previous (e.g., historic) insurance claims filed, processed, and/or paid in relation to entities proximate to the site location. The claims data 202e may comprise, for example, an identification of all insurance claims filed within a predetermined radius of the site (e.g., five hundred (500) yards). According to some embodiments, any or all of the initial input data 202a-e may be sorted, aggregated, ranked, filtered, scrubbed, formatted, and/or otherwise pre-processed at 204.

In some embodiments, the method 200 may comprise computing (and/or otherwise determining or processing) the initial input, at 206. The computing and/or processing may comprise, for example, executing an algorithm and/or rule set that utilizes one or more of the initial input data 202a-e to calculate and/or identify (i) instructions for conducting a site survey and/or (ii) desired sensor locations. The site plan data 202a and/or the location data 202b may be utilized, for example, to identify one or more structures (e.g., buildings, retaining walls, sewer, gas, or water pipes) and/or entities (e.g., schools, businesses, residences) within one or more predetermined distances from the proposed vibratory activity. It may be determined, for example, that an apartment complex is within an expected range of human perception of vibratory activity. In such an embodiment, the contact data 202c may be utilized (e.g., queried) to identify contact information for the residents of the apartment complex. In some embodiments, any insurance claims filed by such residents may be identified from the claims data 202e. In some embodiments, the activity data 202d may be utilized to identify other planned, current, or previous vibration activities within a predetermined range of the site location.

According to some embodiments, the processing at 206 may trigger and/or cause an output, at 208. The output at 208 may, for example, comprise one or more transmissions to one or more remote devices, such as user devices. In the case that the processing at 206 is conducted by a central server, for example, the output at 208 may comprise a transmission of data over the Internet and/or a cellular network. In some embodiments, such output may define and/or cause a generation of an interface such as a webpage, form, and/or application interface, e.g., displayed on a smart phone of a user (e.g., the interface 620 of FIG. 6). In some embodiments, the output 208 may comprise either or both of (i) survey instructions 210 or (ii) sensor location(s) 212. In some embodiments for example, the survey instructions 210 may comprise instructions regarding which specific entities from a plurality of possible entities to contact regarding the proposed vibratory activity. Any entities identified during or by the processing at 206 that are within one of a plurality of predefined distances from the proposed activity, for example, may be listed with their respective contact information (e.g., from the contact data 202c) and/or along with an indication regarding whether any particular entity has previously been involved with insurance claims or losses (e.g., from the claims data 202e). In some embodiments, the survey instructions 210 may include instructions regarding what actions should be taken with respect to certain entities. In the case that a particular entity located near the site location has filed multiple previous insurance claims regarding construction or vibration damage or losses, for example, it may be suggested that such entity be visited in person, asked to sign a waiver, and/or asked to allow placement of a sensor at a location of the entity. In the case that certain entities are identified as being active on social media, it may be suggested that social media contact information be utilized to inform the entity and/or utilized as a vehicle to receive feedback (e.g., during construction activities) from the entity. In some embodiments, the survey instructions 210 may comprise instructions regarding a number, type, and/or location of photographic (or other) baseline evidence to be collected. In the case that a particular entity refuses to respond to notices regarding the proposed vibration activity, for example, photos of the exterior of the entity's building/home may be suggested to assist in establishing a baseline for potential damage reports from the entity at a later time.

According to some embodiments, the method 200 may comprise conducting (or causing or triggering the conducting of) the survey, at 210-1. Any or all instructions provided in the survey instructions at 210, for example, may be carried out, e.g., by a user and/or user device. In some embodiments, the user device may be triggered, actuated, and/or directed by the method 200 and/or a device executing the method 200. According to some embodiments, the user may comprise one or more of site plan designers, engineers, claim handlers, field agents, underwriters, account managers, agents/brokers, customer service representatives, data acquisition partners and/or consultants or service providers, underwriting product customers (or potential customers, e.g., consumers), entities located near the site location, and/or other third parties. An application may be installed on a smart phone or tablet of an entity, for example, where the application is programed to carry out the survey 201-1 (and/or a portion thereof) and/or to utilize sensors in the smart phone to detect and/or measure vibration. In such a manner, for example, the entity's cell phone may be utilized as a hyper-localized sensor to identify levels of vibration experienced by the entity (which may be particularly useful, for example, for an entity that has filed previous vibration-related insurance claims or complaints). According to some embodiments, the conducting of the survey 201-1 may comprise taking or acquiring photographic, video, and/or other pre-activity evidence. It may be directed by the survey instructions 210, for example, that a panoramic photo of a building interior and/or exterior be acquired with respect to a certain entity. According to some embodiments, photos, video, and/or text associated with a location of an entity (e.g., pictures posted of an entity's place of business) may be harvested from one or more social media sites or databases, such as to establish baseline evidence of pre-activity site conditions.

In some embodiments, the method 200 may comprise acquiring survey data, at 210-2. The conduction or execution of the survey at 210-1 may cause the generation, sensing, recordation, storing, and/or acquiring of the data at 210-2, for example. According to some embodiments, the data may be acquired from one or more user devices having appropriate sensors (e.g., executing a specialized application that senses and/or records environmental data, such as localized vibration readings—e.g., acting as a user-operated vibration sensor), one or more third-party devices (e.g., data servers and/or databases), one or more unmanned aerial vehicles (UAVs) and/or unmanned ground vehicles (UGVs) (e.g., pre-programmed or autonomous), and/or other practicable devices. In some embodiments, the data may be acquired in response to and/or in accordance with the survey instructions at 210. The data may comprise, for example, photographs, diagrams, videos, text messages, and/or other data descriptive of pre-vibration activity characteristics of one or more objects at or proximate to the site location. The data may comprise, in some embodiments, one or more measurements, such as distances between two or more locations, soil measurements, thermal imaging, lengths of existing cracks, or size of existing damage or wear, etc.

According to some embodiments, the output at 208 may comprise the sensor location(s) 212. One or more locations for sensors to be placed or installed, for example, may be determined based on various initial input data 202a-e, such as the site plan data 202a (e.g., defining a planned vibration event location) and the location data 202b (e.g., identifying a structure within a predetermined range of potential damage with respect to the planned vibration activity location). It may be determined by the processing at 206, for example, that an aged structure (e.g., more than twenty-five (25) years old) is within one hundred (100) feet of the proposed location of vibratory compaction activities. In some embodiments, an algorithm may dictate that a sensor reading should be taken in such a case at a location that is fifty percent (50%) of the distance between the proposed activity and the aged structure. According to some embodiments, such as in the case that the structure is not as old (e.g., less than ten (10) years old) and/or is of a certain construction type (e.g., masonry as opposed to wood, or vice versa), the specified measurement location distance may be closer to (or farther from) the nearby structure (e.g., seventy-five percent (75%) of the way to the structure from the location). In some embodiments, a sensor location may be determined based on local geology and/or soil conditions or characteristics (e.g., soil and/or rock types), soil stratification, porosity, hydrology, etc. According to some embodiments, a plurality of sensor locations may be defined or identified, such as comprising a sensor array, e.g., configured to capture a plurality of readings around the activity location and/or across the site.

In some embodiments, the method 200 may comprise sensor placement, at 212-1. The sensor location(s) output at 212 may, for example, comprise instructions and/or related data, such as coordinates, defining where one or more sensors should be placed, types of sensors to be placed, recommended sensor settings (e.g., sensitivity and/or frequency of measurement settings), sensor calibration and/or testing instructions, etc. According to some embodiments, such instructions and/or data may be provided to a user, such as a site manager, project engineer, foreman, and/or other on-site personnel, such as a surveyor. In some embodiments, the instructions may be provided via a specialized application executed by a user's mobile electronic device (such as a smart phone or tablet). The coordinates and/or location placement prompt may be output via an interface, for example, that instructs the user how, where, and/or when to place one or more sensors. In some embodiments, the application may initiate a sensor placement process via the interface that walks the user through placement of a plurality of sensors in and around the site location. In some embodiments, the application (and/or a web-based interface) may manage and/or initiate communications with the sensors. The sensors themselves may comprise one or more visual and/or auditory indicators, for example, that are activated by the application based on location data from the sensor (e.g., a Bluetooth® or other short-range network protocol communication between the sensor and the user device). In such a manner, for example, a sensor that is not yet at the appropriate and/or assigned location may output a red light color (e.g., via an LED) and/or no sound, while the sensor light may change colors as it nears the appropriate coordinates (e.g., yellow, then green) and/or output sounds indicative of the proximity to the appropriate location (e.g., a series of beeps that increase in frequency of the pattern and/or increase in frequency of the output sound as the sensor approaches the appropriate location). In such a manner, for example, the sensor, the user's device (e.g., via a specialized application), and/or a remote server (e.g., via a web-based interface) may guide the user to the appropriate placement of each desired sensor. According to some embodiments, the output of the sensor placement process may be provided as an input coordinate set to one or more unmanned vehicles (e.g., UAVs or UGVs, etc.) for automated sensor placement.

According to some embodiments, the method 200 may comprise acquiring sensor readings, at 212-2. The conduction or execution of the sensor placement at 212-1 may cause the generation, sensing, recordation, storing, and/or acquiring of the data at 212-2, for example. According to some embodiments, the data may be acquired from one or more user devices (e.g., executing a specialized application that senses and/or records environmental data such as localized vibration readings—e.g., acting as a user-operated vibration sensor), one or more third-party devices (e.g., building operational data from a building intelligence, automation, and/or alarm system), one or more of the placed sensors, and/or other practicable devices. In some embodiments, the data may be acquired in response to the sensor location(s) instructions at 212. The data may comprise, for example, vibration measurements or readings, soil readings, thermal readings, light readings, temperature readings, moisture readings, distance measurement readings, strain gauge readings, rain gauge readings, wind readings, etc.

In some embodiments, the survey data from 210-2 and/or the sensor readings from 212-2 may be acquired via data collection, at 214. The sensors, third-party systems, and/or user device(s) that sense, capture, and/or record the various data or readings, for example, may transmit and/or provide the data to a centralized server device (e.g., wirelessly, through a router, gateway, and/or cellular network connection). According to some embodiments, the various sensors and/or other devices may be polled by the server to acquire, upload, and/or otherwise acquire the data and/or readings. In some embodiments, the sensors and/or other devices may actively transmit data and/or readings to a remote server in accordance with a predefined schedule (e.g., every minute, every hour, once a day, etc.). According to some embodiments, the data may be acquired in real time or near-real time, such as during construction operations (e.g., during execution of the proposed vibration activity). In such a manner, for example, in the case that a reading exceeds a predefined threshold, an alert may be generated and/or provided to a local device, such as an output device of a vibratory construction equipment device and/or of a user's mobile device, so as to allow for operations to be stopped or altered, e.g., to prevent damage (or further damage).

According to some embodiments, the method 200 may comprise claim handling, at 216. Any or all data acquired during the method 200, such as the initial input data 202a-e, the survey data 210-2, and/or the sensor readings 212-2 may, for example, be utilized to analyze one or more insurance claims (e.g., made by the user and/or by an entity in proximity to the vibration activity). In some embodiments, additional data descriptive of a claimed loss may be obtained (e.g., new pictures of a structure) and compared to the baseline data obtained from the survey 210-1 to determine any differences or changes in the data. In the case that the data has not changed (e.g., a crack existed prior to the vibration activity as evidenced by the survey data 210-1), a claim may be denied. Similarly, damage outside of a particular radial distance from the activity may lead to a denied claim, particularly where vibration measurements that have been taken to confirm actual impacts during the vibration activity conform to expected results. On the other hand, in the case that a claim is supported by vibration readings over certain thresholds, a claim may be paid.

In some embodiments, processing results from claim handling at 216 may be fed back into the processing at 206 to update any logic or algorithms based on empirical results from actual events experienced at one or more sites. The thresholds and/or calculations that dictate where sensors should be placed (and/or how many sensors or what types of sensors), for example, may be updated in the case that sensor locations at a first site during vibratory activity failed to provide adequate warning or documentation for a loss event. While a sensor reading from a device ten (10) feet away from a possible target building failed to trigger an alert at the first site and the building experienced damage, for example, the processing at 206 may be altered to suggest such sensors be placed twenty (20) feet from a structure (i.e., closer to the vibration source), possibly providing better notice of possible readings that exceed thresholds, Similarly, the thresholds themselves may be updated, such as lowered, so that more conservatively triggered alerts may stop, pause, or allow for mitigation of vibration activities before damage occurs. Feedback from the claims handling at 216 may also or alternatively cause changes in the logic that defines the survey instructions at 210, such as by altering the manner, number, and/or type of photographic and/or video evidence required and/or altering social media scraping and/or investigative routines to identify images that may assist in establishing the baseline for visual inspection and/or comparison activities.

Referring now to FIG. 3, a perspective diagram of a system 300 according to some embodiments is shown. The system 300 may, for example, represent a specific geographic location 304 overlaid with (and/or otherwise associated with) a set and/or hierarchy of data layers 310a-g—e.g., charts, maps, plots, graphs, and/or other graphical depictions or representation of geo-referenced data. The system 300 may comprise, for example, a multi-dimensional depiction of the specific geographic location 304 (e.g., depicted for exemplary purposes as a residence or structure) disposed at a particular point identified by coordinates or locations along an “X”, “Y”, and “Z” axis—where the “X” and “Y” axes represent geospatial locations on a surface and the “Z” axis represents a layer element, such as severity, type, magnitude, and/or time. In some embodiments, the data layers 310a-g may comprise representations (and/or data) of vibration activity data for the specific geographic location 304.

A first data layer 310a may, for example, comprise a data layer and/or data set descriptive of a site plan (e.g., the site plan data 202a of FIG. 2 herein). The first data layer 310a, according to some embodiments, may comprise various data points, sub-layers, and/or data attributes (not shown in FIG. 3), such as building corner locations, current topographic data (e.g., digital elevation model), proposed topographic data (e.g., cut and/or fill areas or lines), utility object locations, benchmark locations, and/or proposed vibration event locations, types, expected magnitudes, timing, and/or durations, etc.

A second data layer 310b may comprise, in accordance with some embodiments, a data layer and/or data set descriptive of geographic coordinate information (e.g., the location data 202b of FIG. 2 herein). The second data layer 310b, according to some embodiments, may comprise data defining a plurality of geographic information system (GIS) points, such as described by GPS coordinates, latitude and longitude coordinates, Universal Transverse Mercator (UTM) coordinates, etc. In some embodiments, the location information in the second data layer 310b may comprise data that identifies a plurality of businesses, properties, geographic features, structures, etc.

A third data layer 310c may comprise, in accordance with some embodiments, a data layer and/or data set descriptive of contact information (e.g., the contact data 202c of FIG. 2 herein). The third data layer 310c, according to some embodiments, may comprise data defining one or more mailing addresses, e-mail addresses, account identifiers, names, social media account information, insurance policy information, and/or other identifying and/or contact information for various entities and/or objects. In some embodiments, the contact information may be stored in relation to one or more GIS and/or other coordinates-i.e., may be geo-coded. In such a manner, for example, geo-location points, lines, and/or polygons may be utilized to identify corresponding contact information for entities associated with the identified location.

A fourth data layer 310d may comprise, in accordance with some embodiments, a data layer and/or data set descriptive of activity information (e.g., the activity data 202d of FIG. 2 herein). The fourth data layer 310d, according to some embodiments, may comprise data defining or identifying one or more construction and/or other potentially vibration-causing activities that have occurred, are occurring, or are scheduled to occur. In some embodiments, the activity information may be stored in relation to one or more GIS and/or other coordinates—i.e., may be geo-coded. In such a manner, for example, geo-location points, lines, and/or polygons may be utilized to identify corresponding activity information associated with the identified location. Municipal, state, and/or Federal permit applications may, for example, comprise the activity information.

A fifth data layer 310e may comprise, in accordance with some embodiments, a data layer and/or data set descriptive of claims information (e.g., the claims data 202e of FIG. 2 herein). The fifth data layer 310e, according to some embodiments, may comprise data defining insurance claim information for various entities and/or objects. In some embodiments, the claims information may be stored in relation to one or more GIS and/or other coordinates—i.e., may be geo-coded. In such a manner, for example, geo-location points, lines, and/or polygons may be utilized to identify corresponding claims information for entities and/or objects associated with the identified location. In some embodiments, the claims information may identify a quantity, time and/or date, type, amount of loss, and/or resolution status (e.g., paid, denied, partially paid, fraudulent) for any number of claims associated with entities and/or objects relevant to a particularly geographic location (e.g., point) and/or area (e.g., polygon).

A sixth data layer 310f may comprise, in accordance with some embodiments, a data layer and/or data set descriptive of sensor location data. The sixth data layer 310f, according to some embodiments, may comprise data defining and/or identifying locations for one or more sensor devices, such as a plurality of networked and/or wireless vibration sensors. In some embodiments, the sensor location data may be stored in relation to one or more GIS and/or other coordinates—i.e., may be geo-coded. In such a manner, for example, geo-location points, lines, and/or polygons may be utilized to identify and/or locate or position one or more sensors.

A seventh data layer 310g may comprise, in accordance with some embodiments, a data layer and/or data set descriptive of sensor readings data. The seventh data layer 310g, according to some embodiments, may comprise data descriptive and/or indicative of one or more measurements and/or readings sensed at a particular location by one or more sensor devices, such as a plurality of networked and/or wireless vibration sensors. In some embodiments, the sensor reading data may be stored in relation to one or more GIS and/or other coordinates—i.e., may be geo-coded. In such a manner, for example, readings sensed at one or more specific geo-location points, lines, and/or polygons may be identified, such as to analyze one or more insurance claims relevant to the location at which the data was sensed and/or recorded. In some embodiments, the sensor readings data may also or alternatively comprise one or more photographs, videos, and/or other images or data records for a particular location or area.

According to some embodiments, the data layers 310a-g (and/or the data utilized to generate the data layers 310a-g) may be utilized to compute sensor locations (e.g., to define the sensor location data in the sixth data layer 310f), generate contact lists for entities or objects that may be affected by (e.g., located within an impact threshold ring of) a planned vibration event, and/or analyze the merits of insurance claims associated with a vibration event that has already occurred.

Fewer or more components 304, 310a-g and/or various configurations of the depicted components 304, 310a-g may be included in the system 300 without deviating from the scope of embodiments described herein. In some embodiments, the components 304, 310a-g may be similar in configuration and/or functionality to similarly named and/or numbered components as described herein. In some embodiments, the system 300 (and/or portion thereof) may be utilized by a vibration analysis, management, and/or claim handling program and/or platform programmed and/or otherwise configured to execute, conduct, and/or facilitate the method 200 of FIG. 2, and/or portions thereof described herein.

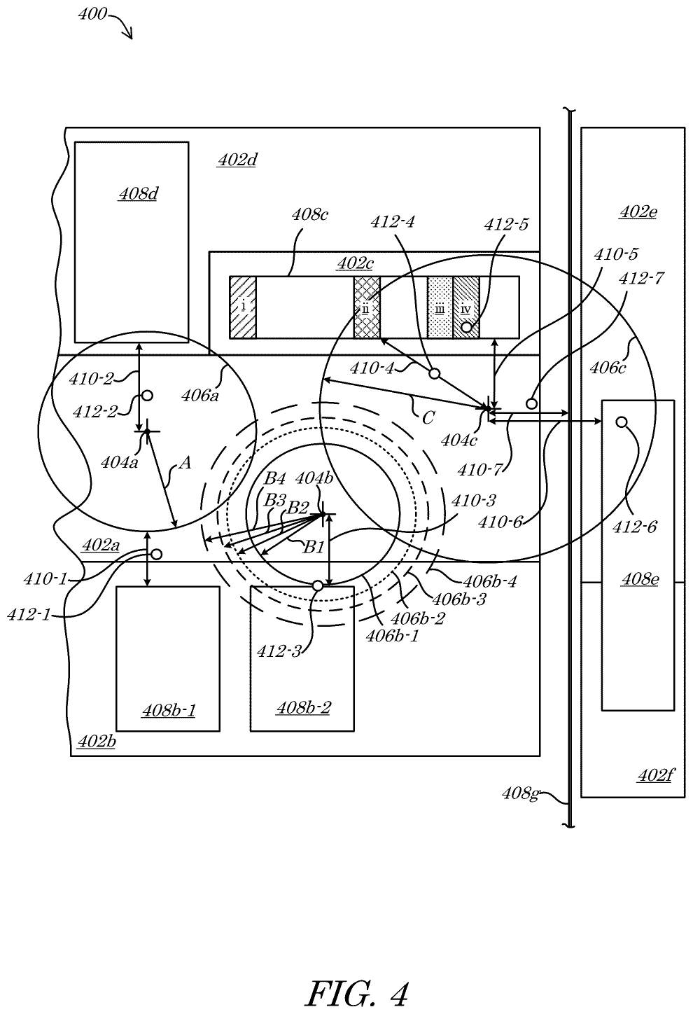

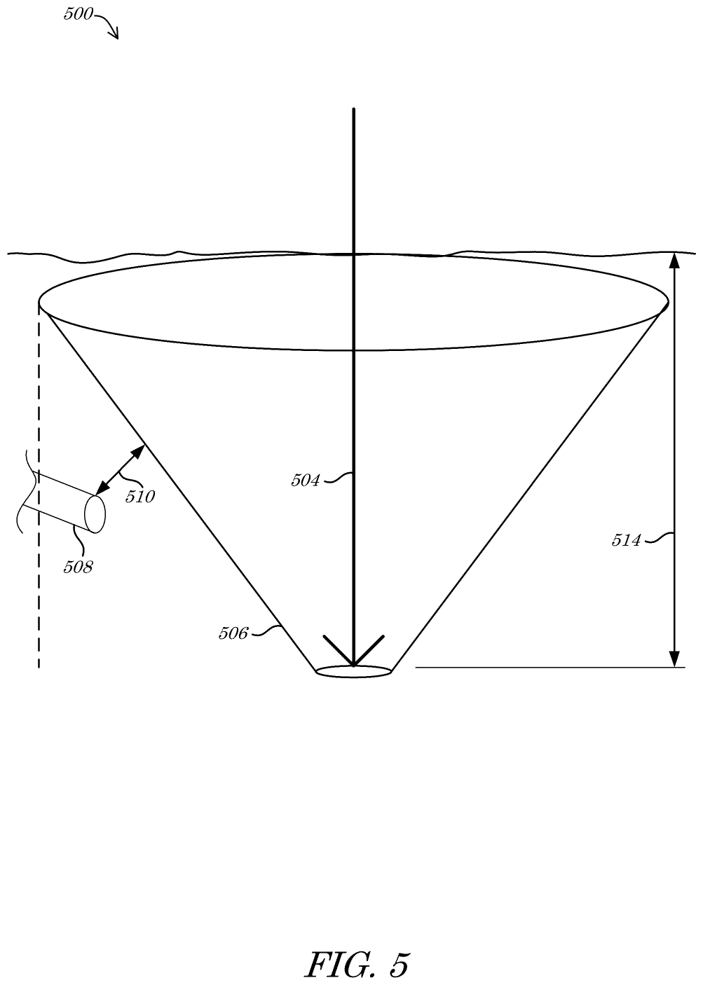

Turning to FIG. 4, a plan view of a system 400 according to some embodiments is shown. The system 400 may, for example, comprise an overhead view of a site plan and/or surrounding location or area associated with a planned vibratory activity. According to some embodiments, any or all data depicted in the system 400 may be obtained from various sources and/or may include site plan data (e.g., the site plan data 202a of FIG. 2 and/or the first data layer 310a of FIG. 3) and/or location data (e.g., the location data 202b of FIG. 2 and/or the second data layer 310b of FIG. 3), that is plotted, stored, and/or represented (e.g., via an interface such as the interface 620 of FIG. 6 herein). According to some embodiments, the system 400 may comprise and/or represent or depict a plurality of properties 402a-f (e.g., location polygons). In some embodiments, a first one of the properties 402a may correspond to and/or identify a site that is planned for development and/or construction. The first property 402a may, for example, comprise a plurality of vibratory activity locations 404a-c. In some embodiments, the vibratory activity locations 404a-c may be obtained and/or defined based on data (e.g., site plan data 202a of FIG. 2 herein) received from a user device and/or file (e.g., a CAD file).

According to some embodiments, each of the vibratory activity locations 404a-c may be associated with, define, and/or correlate to one or more impact threshold rings 406a-c. A first one of the vibratory activity locations 404a may, for example, correlate to and/or define a first impact threshold ring 406a having a radius “A”, as depicted. In some embodiments, a second one of the vibratory activity locations 404b may correlate to and/or define a series or set of second impact threshold rings 406b. A first one of the set of second impact threshold rings 406b-1 may have a radius “B1”, for example, and a second one of the set of second impact threshold rings 406b-2 may have a radius “B2”. According to some embodiments, a third one of the set of second impact threshold rings 406b-3 may have a radius “B3” and/or a fourth one of the set of second impact threshold rings 406b-4 may have a radius “B4”. According to some embodiments, each one of the set of second impact threshold rings 406b may correspond to, define, and/or depict a particular predefined threshold value. The first one of the set of second impact threshold rings 406b-1 may correspond to a structural damage threshold distance (e.g., eleven (11) feet and/or an estimated, expected, or actual PPV of two (2.0) inches per second) from the second one of the vibratory activity locations 404b, for example, and/or the second one of the set of second impact threshold rings 406b-2 may correspond to a likely (e.g., greater than eighty percent (80%) likelihood) architectural damage threshold distance (e.g., thirty-three (33) feet and/or an estimated, expected, or actual PPV of one half (0.5) inches per second) from the second one of the vibratory activity locations 404b. According to some embodiments, the third one of the set of second impact threshold rings 406b-3 may correspond to a possible (e.g., greater than ten percent (10%) chance of) architectural damage threshold distance (e.g., sixty-seven (67) feet and/or an estimated, expected, or actual PPV of two tenths (0.2) inches per second) from the second one of the vibratory activity locations 404b and/or the fourth one of the set of second impact threshold rings 406b-4 may correspond to a human perception threshold distance (e.g., two hundred (200) feet and/or an estimated, expected, or actual PPV of five hundredths (0.05) inches per second) from the second one of the vibratory activity locations 404b. In some embodiments, different impact threshold rings 406a-c may be associated with and/or define or comprise different radius dimensions (e.g., different threshold values). According to some embodiments for example, a third one of the vibratory activity locations 404c may, for example, correlate to and/or define a third impact threshold ring 406c having a radius “C”, which may be larger than the either radius “A” or “B”, as depicted.

In some embodiments, the system 400 may comprise or identify and/or the various properties 402a-f may comprise one or more structures 408b-e, 408g. A second one of the properties 402b may comprise, for example, a first building 408b-1 and/or a second building 408b-1. In some embodiments, a third one of the properties 402c may comprise an apartment building 408c (e.g., having multiple apartments or condominium units “i”, “il”, “ili”, and/or “iv”). According to some embodiments, a fourth one of the properties 402d may comprise a residence 408d and/or a fifth one of the properties 402e and a sixth one of the properties 402f may share a commercial building 408e. In some embodiments, structures may not be associated with or disposed on a particular polygon or typical property parcel. In some embodiments, a pipeline (e.g., gas, oil, sewer, water supply) 408g may pass near or past the first property 402a, e.g., down a street (as depicted but not separately labeled).

According to some embodiments, the site plan and/or location data may be utilized to determine which properties 402b-f and/or structures 408b-e, 408g may be of importance with respect to vibratory activities taking place at the identified vibratory activity locations 404a-c. In some embodiments for example, any structures (or other objects or entities) falling within one or more of the impact threshold rings 406a-c may be identified as relevant (e.g., likely to be “affected by” the proposed vibration activity). Any entity associated with (e.g., owning and/or occupying) any structure 408b-e, 408g that overlaps geographically with the derived impact threshold rings 406a-c, for example, may be identified as an entity for which contact information should be acquired and included on a contact list for a site survey. As depicted in FIG. 4, the second building 408b-2 may fall within each of the second one of the set of second impact threshold rings 406b-2, the third one of the set of second impact threshold rings 406b-3, and the fourth one of the set of second impact threshold rings 406b-4 (while the first building 408b-1 on the same second property 402b does not). In some embodiments, an adjacent orientation of the second property 402b to the first property 402a at which the vibratory activity is planned may cause an identification of the second property 402b as a property of interest with respect to possible preventative measures and/or survey investigation. In some embodiments, however, a property 402b-f may not be adjacent or fully adjacent, but may still be of interest and/or only a portion of an adjacent or proximate structure 408b-e, 408g may be of interest or concern (e.g., with respect to possible or likely vibratory activity damage or insurance claim activity).

As depicted in FIG. 4, for example, only certain units of the apartment building 408c of the third property 402c may fall within the third impact threshold ring 406c (e.g., “il” partially, and “iii” and “iv” entirely). Also as depicted, although the fourth property 402d is not fully adjacent to the first property 402a, the residence 408d may partially fall within the first impact threshold ring 406a. Similarly, while each of the fifth property 402e and the sixth property 402f are located across the street from the first property 402a, the commercial building 408e falls partially within the third impact threshold ring 406c. In some embodiments, distances between the identified structures 408b-e, 408g may be identified and/or computed (e.g., by comparing and/or calculating respective coordinate data). In some embodiments, such measurements may be acquired, derived, and/or deemed important, whether or not a particular structure 408b-e, 408g falls within any particular impact threshold ring 406a-c.

According to some embodiments, a first distance 410-1 may be determined to be between the first building 408b-1 on the second property 402b and an edge, extend, or terminus of the first impact threshold ring 406a. This distance may be of importance, for example, to identify how far outside of the first impact threshold ring 406a the first building 408b-1 is situated. In some embodiments, in the case that the first distance 410-1 is less than a threshold value (e.g., ten (10) feet), the first building 408b-1 may be identified and/or categorized as requiring some level of survey attention, e.g., a notice to the landowner or resident(s). According to some embodiments, a second distance 410-2 may be identified and/or calculated between the residence 408d and the first vibratory activity location 404a. The second distance 410-2 may, for example, be utilized to calculate an expected Peak Particle Velocity (PPV) that may occur at the residence 408d during the vibratory activity that is planned. Similarly, a third distance 410-3 may be calculated or measured between the second building 408b-2 and the second vibratory activity location 404b. The third distance 410-3 may, for example, be utilized to calculate a probability that the second building 408b-2 may experience damage over a certain dollar amount (e.g., a thirty percent (30%) chance that the second building 408b-2 may realize more than one hundred dollars ($100) in damage due to the planned vibratory activity). In some embodiments, a fourth distance 410-4 may be computed between a second apartment “il” in the apartment building 408c and the third vibratory activity location 404c, a fifth distance 410-5 may be computed between the apartment building 408c and the third vibratory activity location 404c, and/or a sixth distance 410-6 may be computed between the commercial building 408e and the third vibratory activity location 404c. According to some embodiments, a seventh distance 410-7 may be computed between the pipeline 408g and the third vibratory activity location 404c (as described with respect to FIG. 5 herein, such distance may or may not comprise a horizontal measurement).

In some embodiments, the site plan and/or location data utilized to generate and/or define the system 400 may be utilized to define and/or identify a plurality of sensor (and/or survey) locations 412-1, 412-2, 412-3, 412-4, 412-5, 412-6, 412-7. As depicted in FIG. 4, for example, a first sensor location 412-1 may be designated between the first building 408b-1 and the extent of the first impact threshold ring 406a, a second sensor location 412-2 may be defined between the residence 408d and the first vibratory activity location 404a, and/or a third sensor location 412-3 may be identified as being coincident with (e.g., for a sensor attached to) the second building 408b-2. According to some embodiments, multiple sensors (e.g., a sensor array) may be placed or suggested for placement with respect to a single planned vibration activity location and/or with respect to a particular structure 408b-e, 408g. As depicted in FIG. 4, for example, a fourth sensor location 412-4 may be identified between the third vibratory activity location 404c and the second apartment “il”, a fifth sensor location 412-5 may be defined within the fourth apartment “iv”, and/or a sixth sensor location 412-6 may be defined within (or on or under) the commercial building 408e. In some embodiments, a seventh sensor location 412-7 may be defined not only between the pipeline 408g and the third vibratory activity location 404c, but may also be defined at a particular elevation, altitude, and/or depth (e.g., as described with reference to FIG. 5 herein).

Fewer or more components 402a-f, 404a-c, 406a-c, 408b-e, 408g, 410, 412 and/or various configurations of the depicted components 402a-f, 404a-c, 406a-c, 408b-e, 408g, 410, 412 may be included in the system 400 without deviating from the scope of embodiments described herein. In some embodiments, the components 402a-f, 404a-c, 406a-c, 408b-e, 408g, 410, 412 may be similar in configuration and/or functionality to similarly named and/or numbered components as described herein. In some embodiments, the system 400 (and/or portion thereof) may be utilized by a vibration analysis, management, and/or claim handling program and/or platform programmed and/or otherwise configured to execute, conduct, and/or facilitate the method 200 of FIG. 2, and/or portions thereof described herein.

Referring now to FIG. 5, a perspective diagram of a system 500 according to some embodiments is shown. The system 500 may, for example, comprise a perspective side or cross-sectional view of a section of earth associated with a planned vibratory activity. According to some embodiments, any or all data depicted in the system 400 may be obtained from various sources and/or may include site plan data (e.g., the site plan data 202a of FIG. 2 and/or the first data layer 310a of FIG. 3) and/or location data (e.g., the location data 202b of FIG. 2 and/or the second data layer 310b of FIG. 3), that is plotted, stored, and/or represented (e.g., via an interface such as the interface 620 of FIG. 6 herein). In some embodiments, the system 500 may generally depict an embodiment in which a proposed vibratory activity at a particular location (e.g., point) 504 comprises a pile driving activity. As depicted in FIG. 5, the pile driving activity may define and/or be modeled to be associated with an impact cone 506. In some embodiments (e.g., as shown), the impact cone may define and/or depict a threshold equation that defines a smaller threshold and/or impact radius at a deeper position than a larger radius at a shallower position (e.g., the ground surface).

According to some embodiments, a pipe or other underground structure 508 may pass near the impact cone 506. As depicted by the dotted vertical line that is oriented with the furthest horizontal extent of the impact cone 506 (e.g., at the ground surface), a plan or bird's-eye view of the system 500 may indicate that the pipe 508 is within an area of impact associated with the location 504. As can be seen in the cross-sectional view of FIG. 5, however, the pipe 508 is actually a distance 510 away from the extent of the impact cone 506. In some embodiments, the distance 510 may be calculated based on the geometry and layout of the system 500, such as to determine a likelihood of the pipe 508 being affected by (e.g., within the impact cone 506) the pile driving at the location 504. According to some embodiments, in the case it is determined that the pipe 508 lies outside of the impact cone 506 (e.g., as depicted for exemplary purposes in FIG. 5), it may be determined that the likelihood of damage to the pipe 508 is below a threshold of concern. In such an embodiment, the owner of the pipe 508 may accordingly not be contacted and/or site survey data with respect to the pipe 508 may not be suggested for gathering. As is shown in FIG. 5, a typical pile driving application may cause vibratory impacts of a certain degree at approximately a forty-five (45) degree angle to the perpendicular and with respect to the lowest point of pile driving impact. As this lowest point may change (e.g., increase in depth) as a pile is driven, a measurement of the depth of the activity 514 may be taken and the impact cone 506 may be recalculated and/or shifted in accordance with the depth 514. In some embodiments, a threshold may be determined for the depth 514 such that any depth beyond the threshold may cause the pipe 508 to fall within the impact cone 506. According to some embodiments, a warning may be transmitted or triggered in the case that the depth 514 meets or approaches the impact threshold for the pipe 508.

Fewer or more components 504, 506, 508, 510, 514 and/or various configurations of the depicted components 504, 506, 508, 510, 514 may be included in the system 500 without deviating from the scope of embodiments described herein. In some embodiments, the components 504, 506, 508, 510, 514 may be similar in configuration and/or functionality to similarly named and/or numbered components as described herein. In some embodiments, the system 500 (and/or portion thereof) may be utilized by a vibration analysis, management, and/or claim handling program and/or platform programmed and/or otherwise configured to execute, conduct, and/or facilitate the method 200 of FIG. 2, and/or portions thereof described herein.

Turning to FIG. 6, a perspective diagram of a system 600 according to some embodiments is shown. The system 600 may, for example, comprise a mobile electronic device (e.g., a user's handheld computational device, such as a smart phone and/or GPS device) 602 in wireless communication with a server 610. According to some embodiments, the mobile electronic device 602 may execute a stored and specially-programmed application that causes a desired or suggested sensor location 612 (e.g., identified and/or located, at least in part, by image data captured by a camera device 616) to be output (e.g., graphically displayed) via an interface 620. As depicted in FIG. 6, the interface 620 may comprise a virtual representation of the area surrounding and/or proximate to the mobile electronic device 602 and/or may include textual instructions 622 and/or a graphical representation 624 of a sensor 632. The interface 620 may be generated utilizing site plan data (e.g., the site plan data 202a of FIG. 2 and/or the first data layer 310a of FIG. 3), GIS location data (e.g., the location data 202b of FIG. 2 and/or the second data layer 310b of FIG. 3), and/or sensor location data (e.g., the sensor location(s) 212 of FIG. 2 and/or the sixth data layer 310f of FIG. 3), provided by the server 610 and/or stored in a remote database 640 for example, and/or may provide visual and/or audible outputs to a user (not shown). In such a manner, for example, the user may be directed to an appropriate location that corresponds to the sensor location 612, e.g., for the particular sensor 632 (e.g., of a plurality of sensors, not separately depicted) to be placed.

In some embodiments, data, such as photographic and/or digital images and/or video, may be captured by the camera device 616 and utilized to determine or compute an orientation of the mobile electronic device 602 (and/or of the camera device 616 thereof) with respect to the sensor location 612. The interface 620 may be utilized to generate an augmented reality view of the area (e.g., comprising and/or defined by a field of view of the camera device 616) that is presented to the user by the mobile electronic device 602. In some embodiments, the graphical representation 624 of the sensor 632 may comprise a virtual representation of the location of the sensor 632 in the real world as augmented and/or overlaid by the interface 620. In such a manner, for example, the user may place the actual physical sensor 632 at an appropriate real-world location (e.g., on the ground in front of the user) that is computed to correspond to the desired coordinates of the sensor location 612. According to some embodiments, location, setup, configuration, and/or readings data from the sensor 632 may be acquired (e.g., wirelessly) by the mobile electronic device 602 (e.g., via Bluetooth® and/or other short-range wireless communication between the sensor 632 and the mobile electronic device 602). In some embodiments, once placed and/or activated (e.g., powered on by the user), the sensor 632 may transmit data directly to the server 610 (e.g., via Wi-Fi®, cellular data transmission, etc.).

Fewer or more components 602, 610, 612, 616, 620, 622, 624, 632, 640 and/or various configurations of the depicted components 602, 610, 612, 616, 620, 622, 624, 632, 640 may be included in the system 600 without deviating from the scope of embodiments described herein. In some embodiments, the components 602, 610, 612, 616, 620, 622, 624, 632, 640 may be similar in configuration and/or functionality to similarly named and/or numbered components as described herein. In some embodiments, the system 600 (and/or portion thereof) may be utilized by a vibration analysis, management, and/or claim handling program and/or platform programmed and/or otherwise configured to execute, conduct, and/or facilitate the method 200 of FIG. 2, and/or portions thereof described herein

Turning to FIG. 7, a block diagram of an apparatus 710 according to some embodiments is shown. In some embodiments, the apparatus 710 may be similar in configuration and/or functionality to any of the user devices 102a-n, 602, the third-party device 106, and/or the controller devices/servers 110, 610 of FIG. 1 and/or FIG. 6 herein, and/or may otherwise comprise a portion of the systems 100, 300, 400, 500, 600 of FIG. 1, FIG. 3, FIG. 4, and/or FIG. 6 herein. The apparatus 710 may, for example, execute, process, facilitate, and/or otherwise be associated with the method 200 described in conjunction with FIG. 2 herein, and/or one or more portions thereof. In some embodiments, the apparatus 710 may comprise a transceiver device 712, one or more processing devices 714, an input device 716, an output device 718, an interface 720, a cooling device 730, and/or a memory device 740 (storing various programs and/or instructions 742 and data 744). According to some embodiments, any or all of the components 712, 714, 716, 718, 720, 730, 740, 742, 744 of the apparatus 710 may be similar in configuration and/or functionality to any similarly named and/or numbered components described herein. Fewer or more components 712, 714, 716, 718, 720, 730, 740, 742, 744 and/or various configurations of the components 712, 714, 716, 718, 720, 730, 740, 742, 744 may be included in the apparatus 710 without deviating from the scope of embodiments described herein.

In some embodiments, the transceiver device 712 may comprise any type or configuration of bi-directional electronic communication device that is or becomes known or practicable. The transceiver device 712 may, for example, comprise a Network Interface Card (NIC), a telephonic device, a cellular network device, a router, a hub, a modem, and/or a communications port or cable. In some embodiments, the transceiver device 712 may be coupled to provide data to a user device (not shown in FIG. 7), such as in the case that the apparatus 710 is utilized to provide a vibration analysis data processing interface (e.g., the interface 720) to a user and/or to provide vibration analysis and/or claims processing results, such as based on vibration activity data, site plan data, location data, survey data, and/or sensor readings data, as described herein. The transceiver device 712 may, for example, comprise a cellular telephone network transmission device that sends signals indicative of vibration and/or claims data processing interface components and/or data processing result-based commands to a user handheld, mobile, and/or telephone device. According to some embodiments, the transceiver device 712 may also or alternatively be coupled to the processing device 714. In some embodiments, the transceiver device 712 may comprise an IR, RF, Bluetooth™, and/or Wi-Fi® network device coupled to facilitate communications between the processing device 714 and another device (such as a user device and/or a third-party device; not shown in FIG. 7).

According to some embodiments, the processing device 714 may be or include any type, quantity, and/or configuration of electronic and/or computerized processor that is or becomes known. The processing device 714 may comprise, for example, an Intel® IXP 2800 network processor or an Intel® XEON™ Processor coupled with an Intel® E7501 chipset. In some embodiments, the processing device 714 may comprise multiple, cooperative, and/or inter-connected processors, microprocessors, and/or micro-engines (e.g., a computational processing device and/or server cluster). According to some embodiments, the processing device 714 (and/or the apparatus 710 and/or portions thereof) may be supplied power via a power supply (not shown), such as a battery, an Alternating Current (AC) source, a Direct Current (DC) source, an AC/DC adapter, solar cells, and/or an inertial generator. In the case that the apparatus 710 comprises a server, such as a blade server, necessary power may be supplied via a standard AC outlet, power strip, surge protector, a PDU, and/or Uninterruptible Power Supply (UPS) device (none of which are shown in FIG. 7).

In some embodiments, the input device 716 and/or the output device 718 are communicatively coupled to the processing device 714 (e.g., via wired and/or wireless connections and/or pathways) and they may generally comprise any types or configurations of input and output components and/or devices that are or become known, respectively. The input device 716 may comprise, for example, a keyboard that allows an operator of the apparatus 710 to interface with the apparatus 710 (e.g., by a user, such as an insurance company analyzing and processing vibration activity site plans and/or vibration activity-related insurance claims, as described herein). The output device 718 may, according to some embodiments, comprise a display screen and/or other practicable output component and/or device. The output device 718 may, for example, provide an augmented reality interface, such as the interface 720 to a user (e.g., via a website). In some embodiments, the interface 720 may comprise portions and/or components of either or both of the input device 716 and the output device 718. According to some embodiments, the input device 716 and/or the output device 718 may, for example, comprise and/or be embodied in an input/output and/or single device such as a touch-screen monitor or display (e.g., that enables both input and output via the interface 720).

In some embodiments, the apparatus 710 may comprise the cooling device 730. According to some embodiments, the cooling device 730 may be coupled (physically, thermally, and/or electrically) to the processing device 714 and/or to the memory device 740. The cooling device 730 may, for example, comprise a fan, heat sink, heat pipe, radiator, cold plate, and/or other cooling component or device or combinations thereof, configured to remove heat from portions or components of the apparatus 710.

The memory device 740 may comprise any appropriate information storage device that is or becomes known or available, including, but not limited to, units and/or combinations of magnetic storage devices (e.g., a hard disk drive), optical storage devices, and/or semiconductor memory devices such as RAM devices, Read Only Memory (ROM) devices, Single Data Rate Random Access Memory (SDR-RAM), Double Data Rate Random Access Memory (DDR-RAM), and/or Programmable Read Only Memory (PROM). The memory device 740 may, according to some embodiments, store one or more of vibration analysis instructions 742-1, survey instructions 742-2, sensor setup instructions 742-3, interface instructions 742-4, site plan data 744-1, location data 744-2, contact data 744-3, activity data 744-4, claims data 744-5, survey data 744-6, and/or sensor data 744-7. In some embodiments, the vibration analysis instructions 742-1, survey instructions 742-2, sensor setup instructions 742-3, interface instructions 742-4, site plan data 744-1, location data 744-2, contact data 744-3, activity data 744-4, claims data 744-5, survey data 744-6, and/or sensor data 744-7 may be utilized by the processing device 714 to provide output information via the output device 718 and/or the transceiver device 712.

According to some embodiments, the vibration analysis instructions 742-1 may be operable to cause the processing device 714 to process site plan data 744-1, location data 744-2, contact data 744-3, activity data 744-4, claims data 744-5, survey data 744-6, and/or sensor data 744-7. Site plan data 744-1, location data 744-2, contact data 744-3, activity data 744-4, claims data 744-5, survey data 744-6, and/or sensor data 744-7 received via the input device 716 and/or the transceiver device 712 may, for example, be analyzed, sorted, filtered, decoded, decompressed, ranked, scored, plotted, and/or otherwise processed by the processing device 714 in accordance with the vibration analysis instructions 742-1. In some embodiments, site plan data 744-1, location data 744-2, contact data 744-3, activity data 744-4, claims data 744-5, survey data 744-6, and/or sensor data 744-7 may be fed (e.g., input) by the processing device 714 through one or more mathematical and/or statistical formulas and/or models in accordance with the vibration analysis instructions 742-1 to identify entities and/or objects that may be implicated by a proposed vibratory activity and/or probabilities of and/or different levels of possible damage or loss for such objects and/or entities, in accordance with embodiments described herein.

In some embodiments, the survey instructions 742-2 may be operable to cause the processing device 714 to process site plan data 744-1, location data 744-2, contact data 744-3, activity data 744-4, claims data 744-5, survey data 744-6, and/or sensor data 744-7. Site plan data 744-1, location data 744-2, contact data 744-3, activity data 744-4, claims data 744-5, survey data 744-6, and/or sensor data 744-7 received via the input device 716 and/or the transceiver device 712 may, for example, be analyzed, sorted, filtered, decoded, decompressed, ranked, scored, plotted, and/or otherwise processed by the processing device 714 in accordance with the survey instructions 742-2. In some embodiments, site plan data 744-1, location data 744-2, contact data 744-3, activity data 744-4, claims data 744-5, survey data 744-6, and/or sensor data 744-7 may be fed (e.g., input) by the processing device 714 through one or more mathematical and/or statistical formulas and/or models in accordance with the survey instructions 742-2 to create a list of entities to be contacted and/or create a list of desired baseline evidence (and/or locations and/or descriptions thereof), in accordance with embodiments described herein.

According to some embodiments, the sensor setup instructions 742-3 may be operable to cause the processing device 714 to process site plan data 744-1, location data 744-2, contact data 744-3, activity data 744-4, claims data 744-5, survey data 744-6, and/or sensor data 744-7. Site plan data 744-1, location data 744-2, contact data 744-3, activity data 744-4, claims data 744-5, survey data 744-6, and/or sensor data 744-7 received via the input device 716 and/or the transceiver device 712 may, for example, be analyzed, sorted, filtered, decoded, decompressed, ranked, scored, plotted, and/or otherwise processed by the processing device 714 in accordance with the sensor setup instructions 742-3. In some embodiments, site plan data 744-1, location data 744-2, contact data 744-3, activity data 744-4, claims data 744-5, survey data 744-6, and/or sensor data 744-7 may be fed (e.g., input) by the processing device 714 through one or more mathematical and/or statistical formulas and/or models in accordance with the sensor setup instructions 742-3 to identify one or more desired sensor locations, provide sensor configuration and/or setup instructions, and/or to initiate and/or conduct sensor array testing and/or calibration, in accordance with embodiments described herein.

In some embodiments, the interface instructions 742-4 may be operable to cause the processing device 714 to process site plan data 744-1, location data 744-2, contact data 744-3, activity data 744-4, claims data 744-5, survey data 744-6, and/or sensor data 744-7. Site plan data 744-1, location data 744-2, contact data 744-3, activity data 744-4, claims data 744-5, survey data 744-6, and/or sensor data 744-7 received via the input device 716 and/or the transceiver device 712 may, for example, be analyzed, sorted, filtered, decoded, decompressed, ranked, scored, plotted, and/or otherwise processed by the processing device 714 in accordance with the interface instructions 742-4. In some embodiments, site plan data 744-1, location data 744-2, contact data 744-3, activity data 744-4, claims data 744-5, survey data 744-6, and/or sensor data 744-7 may be fed (e.g., input) by the processing device 714 through one or more mathematical and/or statistical formulas and/or models in accordance with the interface instructions 742-4 to generate a graphical user interface that guides and/or prompts a user to conduct survey and/or sensor placement/setup activities, in accordance with embodiments described herein.

Any or all of the exemplary instructions 742 and data types 744 described herein and other practicable types of data may be stored in any number, type, and/or configuration of memory devices that is or becomes known. The memory device 740 may, for example, comprise one or more data tables or files, databases, table spaces, registers, and/or other storage structures. In some embodiments, multiple databases and/or storage structures (and/or multiple memory devices 740) may be utilized to store information associated with the apparatus 710. According to some embodiments, the memory device 740 may be incorporated into and/or otherwise coupled to the apparatus 710 (e.g., as shown) or may simply be accessible to the apparatus 710 (e.g., externally located and/or situated). According to some embodiments, the apparatus 710 may comprise a system and/or a portion of a system that may, for example, include additional devices and/or objects, local or remote, than are depicted in FIG. 7. The apparatus 710 may comprise, for example, a system for utilizing user vibration activity-related input to compute survey data requirements and/or sensor locations, e.g., based on an analysis of proposed vibratory activities with respect to geographically proximate objects and/or entities, as described herein.

Referring to FIG. 8A, FIG. 8B, FIG. 8C, FIG. 8D, and FIG. 8E, perspective diagrams of exemplary data storage devices 840a-e according to some embodiments are shown. The data storage devices 840a-e may, for example, be utilized to store instructions and/or data such as the vibration analysis instructions 742-1, survey instructions 742-2, sensor setup instructions 742-3, interface instructions 742-4, site plan data 744-1, location data 744-2, contact data 744-3, activity data 744-4, claims data 744-5, survey data 744-6, and/or sensor data 744-7, each of which is described in reference to FIG. 7 herein. In some embodiments, instructions stored on the data storage devices 840a-e may, when executed by one or more threads, cores, and/or processors (such as the processing device 714 of FIG. 7), cause the implementation of and/or facilitate the method 200 described in conjunction with FIG. 2 herein, and/or portions thereof.

According to some embodiments, a first data storage device 840a may comprise one or more various types of internal and/or external hard drives. The first data storage device 840a may, for example, comprise a data storage medium 846 that is read, interrogated, and/or otherwise communicatively coupled to and/or via a disk reading device 848. In some embodiments, the first data storage device 840a and/or the data storage medium 846 may be configured to store information utilizing one or more magnetic, inductive, and/or optical means (e.g., magnetic, inductive, and/or optical-encoding). The data storage medium 846, depicted as a first data storage medium 846a for example (e.g., breakout cross-section “A”), may comprise one or more of a polymer layer 846a-1, a magnetic data storage layer 846a-2, a non-magnetic layer 846a-3, a magnetic base layer 846a-4, a contact layer 846a-5, and/or a substrate layer 846a-6. According to some embodiments, a magnetic read head 846a may be coupled and/or disposed to read data from the magnetic data storage layer 846a-2.

In some embodiments, the data storage medium 846, depicted as a second data storage medium 846b for example (e.g., breakout cross-section “B”), may comprise a plurality of data points 846b-2 disposed with the second data storage medium 846b. The data points 846b-2 may, in some embodiments, be read and/or otherwise interfaced with via a laser-enabled read head 848b disposed and/or coupled to direct a laser beam through the second data storage medium 846b.

In some embodiments, a second data storage device 840b may comprise a CD, CD-ROM, DVD, Blu-Ray™ Disc, and/or other type of optically-encoded disk and/or other storage medium that is or becomes know or practicable. In some embodiments, a third data storage device 840c may comprise a USB keyfob, dongle, and/or other type of flash memory data storage device that is or becomes know or practicable. In some embodiments, a fourth data storage device 840d may comprise RAM of any type, quantity, and/or configuration that is or becomes practicable and/or desirable. In some embodiments, the fourth data storage device 840d may comprise an off-chip cache such as a Level 2 (L2) cache memory device. According to some embodiments, a fifth data storage device 840e may comprise an on-chip memory device such as a Level 1 (L1) cache memory device.

The data storage devices 840a-e may generally store program instructions, code, and/or modules that, when executed by a processing device cause a particular machine to function in accordance with one or more embodiments described herein. The data storage devices 840a-e depicted in FIG. 8A, FIG. 8B, FIG. 8C, FIG. 8D, and FIG. 8E are representative of a class and/or subset of computer-readable media that are defined herein as “computer-readable memory” (e.g., non-transitory memory devices as opposed to transmission devices or media).

The terms “computer-readable medium” and “computer-readable memory” refer to any medium that participates in providing data (e.g., instructions) that may be read by a computer and/or a processor. Such a medium may take many forms, including but not limited to non-volatile media, volatile media, and other specific types of transmission media. Non-volatile media include, for example, optical or magnetic disks and other persistent memory. Volatile media include DRAM, which typically constitutes the main memory. Other types of transmission media include coaxial cables, copper wire, and fiber optics, including the wires that comprise a system bus coupled to the processor.

Common forms of computer-readable media include, for example, a floppy disk, a flexible disk, hard disk, magnetic tape, any other magnetic medium, a CD-ROM, Digital Video Disc (DVD), any other optical medium, punch cards, paper tape, any other physical medium with patterns of holes, a RAM, a PROM, an EPROM, a FLASH-EEPROM, a USB memory stick, a dongle, any other memory chip or cartridge, a carrier wave, or any other medium from which a computer can read. The terms “computer-readable medium” and/or “tangible media” specifically exclude signals, waves, and wave forms or other intangible or transitory media that may nevertheless be readable by a computer.

Various forms of computer-readable media may be involved in carrying sequences of instructions to a processor. For example, sequences of instruction (i) may be delivered from RAM to a processor, (ii) may be carried over a wireless transmission medium, and/or (iii) may be formatted according to numerous formats, standards or protocols. For a more exhaustive list of protocols, the term “network” is defined herein and includes many exemplary protocols that are also applicable here.

### III. Terms and Rules of Interpretation

Throughout the description herein and unless otherwise specified, the following terms may include and/or encompass the example meanings provided in this section. These terms and illustrative example meanings are provided to clarify the language selected to describe embodiments both in the specification and in the appended claims, and accordingly, are not intended to be limiting. While not generally limiting and while not limiting for all described embodiments, in some embodiments, the terms are specifically limited to the example definitions and/or examples provided. Other terms are defined throughout the present description.

Some embodiments described herein are associated with a “module”. As utilized herein, the term “module” may generally be descriptive of any combination of hardware, electronic circuitry and/or other electronics (such as logic chips, logical gates, and/or other electronic circuit elements or components), hardware (e.g., physical devices such as hard disks, solid-state memory devices, and/or computer components such as processing units or devices), firmware, and/or software or microcode.

Some embodiments described herein are associated with a “user device”, a “remote device”, or a “network device”. As used herein, each of a “user device” and a “remote device” is a subset of a “network device”. The “network device”, for example, may generally refer to any device that can communicate via a network, while the “user device” may comprise a network device that is owned and/or operated by or otherwise associated with a particular user (and/or group of users—e.g., via shared login credentials and/or usage rights), and while a “remote device” may generally comprise a device remote from a primary device or system component and/or may comprise a wireless and/or portable network device. Examples of user, remote, and/or network devices may include, but are not limited to: a PC, a computer workstation, a computer server, a printer, a scanner, a facsimile machine, a copier, a Personal Digital Assistant (PDA), a storage device (e.g., a disk drive), a hub, a router, a switch, and a modem, a video game console, or a wireless or cellular telephone. User, remote, and/or network devices may, in some embodiments, comprise one or more network components.

As used herein, the term “network component” may refer to a user, remote, or network device, or a component, piece, portion, or combination of user, remote, or network devices. Examples of network components may include a Static Random Access Memory (SRAM) device or module, a network processor, and a network communication path, connection, port, or cable.

In addition, some embodiments are associated with a “network” or a “communication network.” As used herein, the terms “network” and “communication network” may be used interchangeably and may refer to any object, entity, component, device, and/or any combination thereof that permits, facilitates, and/or otherwise contributes to or is associated with the transmission of messages, packets, signals, and/or other forms of information between and/or within one or more network devices. Networks may be or include a plurality of interconnected network devices. In some embodiments, networks may be hard-wired, wireless, virtual, neural, and/or any other configuration or type that is or becomes known. Communication networks may include, for example, devices that communicate directly or indirectly, via a wired or wireless medium such as the Internet, intranet, a Local Area Network (LAN), a Wide Area Network (WAN), a cellular telephone network, a Bluetooth® network, a Near-Field Communication (NFC) network, a Radio Frequency (RF) network, a Virtual Private Network (VPN), Ethernet (or IEEE 802.3), Token Ring, or via any appropriate communications means or combination of communications means. Exemplary protocols include but are not limited to: Bluetooth™, Time Division Multiple Access (TDMA), Code Division Multiple Access (CDMA), Global System for Mobile communications (GSM), Enhanced Data rates for GSM Evolution (EDGE), General Packet Radio Service (GPRS), Wideband CDMA (WCDMA), Advanced Mobile Phone System (AMPS), Digital AMPS (D-AMPS), IEEE 802.11 (WI-FI), IEEE 802.3, SAP, the best of breed (BOB), and/or system to system (S2S).

As used herein, the terms “information” and “data” may be used interchangeably and may refer to any data, text, voice, video, image, message, bit, packet, pulse, tone, waveform, and/or other type or configuration of signal and/or information. Information may comprise information packets transmitted, for example, in accordance with the Internet Protocol Version 6 (IPv6) standard. Information may, according to some embodiments, be compressed, encoded, encrypted, and/or otherwise packaged or manipulated in accordance with any method that is or becomes known or practicable.

The term “indication”, as used herein (unless specified otherwise), may generally refer to any indicia and/or other information indicative of or associated with a subject, item, entity, and/or other object and/or idea. As used herein, the phrases “information indicative of” and “indicia” may be used to refer to any information that represents, describes, and/or is otherwise associated with a related entity, subject, or object. Indicia of information may include, for example, a code, a reference, a link, a signal, an identifier, and/or any combination thereof and/or any other informative representation associated with the information. In some embodiments, indicia of information (or indicative of the information) may be or include the information itself and/or any portion or component of the information. In some embodiments, an indication may include a request, a solicitation, a broadcast, and/or any other form of information gathering and/or dissemination

In some embodiments, one or more specialized machines, such as a computerized processing device, a server, a remote terminal, and/or a customer device may implement the various practices described herein. A computer system of an insurance quotation and/or risk analysis processing enterprise may, for example, comprise various specialized computers that interact to analyze, process, and/or transform data in a modular fashion as described herein. In some embodiments, such modular data processing may provide various advantages, such as reducing the number and/or frequency of data calls to data storage devices, which may accordingly increase processing speeds for instances of data processing model executions. As the modular approach detailed herein also allows for storage of a single, modular set of programming code, as opposed to multiple complete version of code having variance therein, the taxation on memory resources for a data processing system may also be reduced.

The present disclosure provides, to one of ordinary skill in the art, an enabling description of several embodiments and/or inventions. Some of these embodiments and/or inventions may not be claimed in the present application, but may nevertheless be claimed in one or more continuing applications that claim the benefit of priority of the present application. Applicant reserves the right to file additional applications to pursue patents for subject matter that has been disclosed and enabled, but not claimed in the present application.

What is claimed is:

1. A system for analyzing vibration activity data to direct vibration-related data collection, comprising:
a data transceiver device;
at least one interface generation device in communication with the data transceiver;
a computational server cluster communicatively coupled to the data transceiver device, the computational server cluster comprising a plurality of cooperative processing units, and the computational server cluster being in communication with the interface generation device; and
a computational logic data storage device in communication with the computational server cluster, the computational logic data storage device storing (i) a vibration analysis algorithm and (ii) at least one programmatic logic routine defining required survey data and suggested sensor location data, wherein execution of the at least one programmatic logic routine by the computational server cluster, results in:
receiving, by the data transceiver device and from a remote mobile user device via a first electronic network pathway, initial input comprising data descriptive of a proposed vibration activity at a first location;
routing, by the data transceiver device and to the computational server cluster, the data descriptive of the proposed vibration activity at the first location;
identifying, by the computational server cluster and by executing the vibration analysis algorithm, at least one second location that has a likelihood of being affected by the proposed vibration activity at the first location;
computing, by the computational server cluster and based at least in part on (a) the identified at least one second location, (b) an age of a structure at the identified at least one second location, and (c) a geologic characteristic at the identified at least one second location, a plurality of suggested sensor locations;
transmitting, to the at least one interface generation device, coordinate information descriptive of the plurality of suggested sensor locations, wherein the coordinate information comprises data defining a unique coordinate in a coordinate system for each of the plurality of suggested sensor locations; and
outputting, by the at least one interface generation device and via the remote mobile user device, and prior to placement of any sensors, a graphical indication of the coordinate information descriptive of the plurality of suggested sensor locations.

2. The system of claim 1, wherein the graphical indication of the coordinate information descriptive of the plurality of suggested sensor locations comprises an augmented reality interface that overlays a visual indication of each of the unique coordinates with a representation of an area within a field of view of a camera of the remote mobile user device.

3. The system of claim 1, wherein the initial input comprises data defining values for (i) a GIS coordinate of the proposed vibration activity at the first location, (ii) a type of the proposed vibration activity at the first location, and (iii) geologic data for the first location.

4. The system of claim 1, wherein the identifying of the at least one second location that has a likelihood of being affected by the proposed vibration activity at the first location, comprises:
identifying a distance between the at least one second location that has a likelihood of being affected by the proposed vibration activity at the first location, and the first location;
calculating, utilizing the initial input and the identified distance, a peak particle velocity for the at least one second location associated with the proposed vibration activity at the first location;
comparing the calculated peak particle velocity for the at least one second location to stored peak particle velocity threshold data; and
identifying that the calculated peak particle velocity for the at least one second location exceeds the at least one threshold defined by the stored peak particle velocity threshold data.

5. The system of claim 1, wherein the execution of the at least one programmatic logic routine by the computational server cluster, further results in:
receiving, by the data transceiver device and from a sensor placed at one of the plurality of suggested sensor locations, vibration activity data due to an execution of the proposed vibration activity.

6. The system of claim 5, wherein the execution of the at least one programmatic logic routine by the computational server cluster, further results in:
comparing, by the computational server cluster, the received vibration activity data to at least one peak particle velocity threshold; and
transmitting, to the at least one interface generation device and in the case that a value of the received vibration activity data exceeds the at least one peak particle velocity threshold, an alert to stop the execution of the vibration activity.

7. The system of claim 6, wherein the execution of the at least one programmatic logic routine by the computational server cluster, further results in:
generating, by the at least one interface generation device and in response to the receiving of the alert, a graphical alert notification; and
outputting, via an output device, the graphical alert notification.

8. The system of claim 7, wherein the output device comprises an output device of a construction equipment object.

9. The system of claim 1, wherein the execution of the at least one programmatic logic routine by the computational server cluster, further results in:
identifying, by the computational server cluster and by querying one or more data storage devices, contact information for an entity associated with the at least one second location.

10. The system of claim 9, wherein the contact information for an entity associated with the at least one second location comprises social media account information and wherein the execution of the at least one programmatic logic routine by the computational server cluster, further results in:
identifying, by the computational server cluster and by accessing the social media account, first imagery descriptive of the at least one second location.

11. The system of claim 10, wherein the execution of the at least one programmatic logic routine by the computational server cluster, further results in:
receiving, by the data transceiver device and after an initiation of the proposed vibration activity at the first location, second imagery descriptive of the at least one second location;
comparing, by the computational server cluster, the first imagery and the second imagery; and
determining, by the computational server cluster and based on the comparison of the first and second imagery, that no damage has occurred at the second location due to the initiation of the proposed vibration activity.

12. A system for analyzing and documenting pre-vibration activity data, comprising:
a data transceiver device;
at least one interface generation device in communication with the data transceiver;
a computational server cluster communicatively coupled to the data transceiver device, the computational server cluster comprising a plurality of cooperative processing units, and the computational server cluster being in communication with the interface generation device; and
a computational logic data storage device in communication with the computational server cluster, the computational logic data storage device storing (i) GIS map data, (ii) vibration threshold data, (iii) a vibration analysis algorithm and (iv) at least one programmatic logic routine defining required survey data and suggested sensor location data, wherein execution of the at least one programmatic logic routine by the computational server cluster, results in:
receiving, by the data transceiver device and from a remote user device via a first electronic network pathway, initial input comprising data descriptive of a proposed vibration activity at a first location, the data descriptive of the proposed vibration activity at the first location comprising data defining values for (i) a GIS coordinate of the proposed vibration activity at the first location, (ii) a type of the proposed vibration activity at the first location, and (iii) geologic data for the first location;
routing, by the data transceiver device and to the computational server cluster, the data descriptive of the proposed vibration activity at the first location;
identifying, by the computational server cluster and based on the GIS coordinate of the proposed vibration activity at the first location and the GIS map data, a plurality of structures within a predetermined proximity of the first location;
computing, by the computational server cluster and by executing the vibration analysis algorithm utilizing the type of the proposed vibration activity and the geologic data for the first location, an estimated level of vibration that at the proposed vibration activity at the first location would cause to occur at each structure of the plurality of structures;
identifying, by the computational server cluster and based on the estimated vibration levels and stored vibration threshold data, that an estimated vibration level at a first one of the structures exceeds a human perception threshold;
outputting, by the at least one interface generation device, a graphical indication of a spatial relationship between the identified first one of the structures and the first location;
identifying, by the computational server cluster and by querying one or more data storage devices, contact information for an entity associated with the first one of the structures; and
transmitting, to the remote user device, (a) the contact information and (b) instructions to contact the entity in advance of initiating the proposed vibration activity at the first location.

13. The system of claim 12, wherein the execution of the at least one programmatic logic routine by the computational server cluster, further results in:
identifying, by the computational server cluster and based on the estimated vibration levels and the stored vibration threshold data, that the estimated vibration level at the first one of the structures does not exceed an expected damage threshold.

14. The system of claim 12, wherein the contact information comprises social media account information.

15. The system of claim 14, wherein the execution of the at least one programmatic logic routine by the computational server cluster, further results in:
automatically harvesting, by the computational server cluster, prior to initiating the proposed vibration activity at the first location and utilizing the social media account information, photos or videos of the first one of the structures.

16. The system of claim 12, wherein the execution of the at least one programmatic logic routine by the computational server cluster, further results in:
receiving, by the data transceiver device and from an application executed on a cell phone of the entity at the first one of the structures, vibration activity data due to an execution of the proposed vibration activity at the first location.

17. The system of claim 16, wherein the execution of the at least one programmatic logic routine by the computational server cluster, further results in:
comparing, by the computational server cluster, the received vibration activity data to at least one peak particle velocity threshold; and
transmitting, to the at least one interface generation device and in the case that a value of the received vibration activity data exceeds the at least one peak particle velocity threshold, an alert to stop the execution of the vibration activity.
